(19) United States
(12) Patent Application Publication
(10) Pub. No.: US 2007/0010083 A1
(43) Pub. Date: Jan. 11, 2007

(54) Method of realizing direct bonding between metal wires and copper pads by means of thermosonic wire bonding using shielding gas spraying device

(76) Inventors: Jong-Ning Aoh, Min-Hsiung (TW); Cheng-Li Chuang, Min-Hsiung (TW)

Correspondence Address: SCHMEISER, OLSEN & WATTS, 22 CENTURY HILL DRIVE, SUITE 302, LATHAM, NY, 12110, US

(21) Appl. No.: 11/176,866

(22) Filed: Jul. 7, 2005

(51) Int. Cl. H01L 21/44

(52) U.S. Cl. 438/612; 438/617

(57) ABSTRACT

Discloses is a method of realizing direct bonding between metal wires and copper pads by means of thermosonic wire bonding using a shielding gas spraying device, where a shielding gas is provided between metal wires and a chip with copper pads during thermosonic wire bonding to form a gas shielding zone around a wire bonding zone of a thermosonic wire bonder, to effectively prevent oxidization of the chips with copper pads at elevated temperature of a heating stage of the thermosonic wire bonder; thus, the provision of the shielding gas spraying device according to this invention allows the metal wires to be directly bonded to the chips with copper pads by means of thermosonic wire bonding process, and overcomes the problem caused by the copper oxide film, thereby meeting the demand of high bondability required by the semiconductor packaging industry, and significantly improving the bonding strength and reliability of the metal wires and chip with copper pads.

### FIELD OF INVENTION

This invention relates to a method of realizing direct bonding between metal wires and copper pads by means of thermosonic wire bonding using a shielding gas spraying device, where a shielding gas spraying device is employed to realize the direct bonding process between metal wires and copper pads by means of thermosonic wire bonding.

### BACKGROUND

Along with the miniaturization of components and quick development of the process of manufacturing semiconductors to submicron level, the component density per unit area increases dramatically such that the reduced interconnects dimension between the components induces higher electric resistance and the narrow line widths increase the parasitic capacitance thereby resulting in significant signal delays. With the inevitable trend of miniaturization, an optimum measure of reducing the signal delays is to employ dielectric materials with a low dielectric constant and replace the conventional aluminum interconnects with copper of better electrical conductivity. However, the introduction of copper interconnects have resulted in significant impacts in the packaging process due to the entire different mechanisms involved in the oxidization of copper and aluminum metals. For aluminum, a self-passivation is easily formed on its surface to prevent oxidation of the aluminum underneath the self-passivation layer, where the aluminum oxide film is scrubbed off by ultrasonic power during the thermosonic wire bonding process so as to ensure bonding between the metal wires and the aluminum pads. Copper, on the contrary, is easily oxidized under the atmosphere, since the copper oxide film does not provide the same self-passivation effect as the aluminum oxide film does, such that the copper oxide of the copper pads film would continue to grow on the surfaces of the copper pads. Not only does such a copper oxide film on the copper pads become a bottleneck in the thermosonic wire bonding process, it adversely affects the mechanical and physical properties of copper pads. The thermosonic wire bonding process is widely employed in the packaging industry. The underlying principles involved in the thermosonic wire bonding process include ultrasonic bonding and thermal compression bonding, where a heating stage provides heat that serves as the activation energy required for the atomic inter-diffusion bonding between the metal wires and metal pads, as well as ultrasonic power that results in a temperature rise at the bonding interface due to friction between the wires and metal pads to facilitate atomic inter-diffusion between the metal pads and metal wires thereby forming good ball bond or stitch bonds. Thus, in a thermosonic wire bonding process, the temperature required for the heating stage during the thermal compression bonding should be lower enough to prevent the semiconductor components from thermal damages. Generally speaking, the temperature of the heating stage required for thermosonic wire bonding is set within the range of 120° C. to 220° C. The appropriate bonding temperature range (120° C. to 220° C.) for a thermosonic wire bonder, however, does not allow a problem-free bonding between the metal wires and the chip with copper pads, as the surfaces of copper pads under such a temperature range are easily oxidized and the thickness of the oxide film increases with increasing stage temperature, as shown in FIG. 1, wherein the copper oxide film on the copper pads significantly affects the bondability and bonding strength of the thermosonic bonds. The oxide film becomes a barrier for the atomic inter-diffusion at wires copper pads interface and hinders the wires from bonded to copper pads. The copper oxide film on the copper pads surface cannot serve as a self-passivation layer to prevent oxidation of the parent metal underneath the oxide layer as the aluminum oxide film can, and the copper oxide film on the copper pads cannot be scrubbed off by the ultrasonic power generated by the thermosonic wire bonder, whereby the copper oxide film becomes a barrier for the bonding of metal wires copper pads and the oxidation of copper of is a serious bottleneck in the thermosonic wire bonding process for bonding metal wires to copper pads. A development for new technology capable of preventing or reducing the oxidization of the copper pads in the thermosonic wire bonding process, and overcoming the problem caused by the copper oxide film to allow a direct bonding of metal wires to copper pads in the thermosonic wire bonding process is thus essential, thereby meeting the demand of high bondability required by the semiconductor packaging industry, ensuring the superior performance of the chips with copper interconnects, and significantly improving the quality and reliability of the thermosonic bonding of metal wires and chips with copper pads.

### SUMMARY OF INVENTION

In view of the shortcomings of the thermosonic wire bonding process adopted in the conventional semiconductor components, the invention discloses a method of realizing direct bonding between metal wires and copper pads by means of thermosonic wire bonding using a shielding gas spraying device, where a shielding gas spraying device is employed to realize the direct bonding between metal wires and copper pads by means of thermosonic wire bonding.

Thus, it is a primary objective of this invention to provide a method of realizing direct bonding between metal wires and copper pads by means of thermosonic wire bonding using a shielding gas spraying device that would prevent oxidization of copper pads, allow direct bonding of metal wires to chips with copper pads, and ensure superior performance of the chips with copper pads.

It is another objective of this invention to provide a method of realizing direct bonding between metal wires and copper pads by means of thermosonic wire bonding using a shielding gas spraying device, where a shielding gas spraying device is able to adjust the gas-spraying orientation in accordance with the chip dimensions, such that the device may meet the demands of various chip sizes without affecting the handling space required for manual wire-inserting operation performed by the operators.

It is another objective of this invention to provide a method of realizing direct bonding between metal wires and copper pads by means of thermosonic wire bonding using a shielding gas spraying device, where the metal wires are directly bonded to chips with copper pads at high bondability meeting the industry standard while improving the bonding strength and reliability during the thermosonic wire bonding process between copper metal wires and chip with copper pads.

To achieve the above objectives, this invention discloses a method of realizing direct bonding between metal wires and copper pads by means of thermosonic wire bonding using a shielding gas spraying device, comprising the steps of: providing a shielding gas spraying device during the thermosonic wire bonding between copper metal wires and chips with copper pads; providing a shielding gas to shield the surface of the chip with copper pads, wherein the shielding gas forms a shielding zone above the chip with copper pads to prevent air from entering the shielding zone and the surfaces of copper pads from oxidization, so as to allow direct bonding between metal wires and chip with copper pads.

### BRIEF DESCRIPTION OF THE DRAWINGS

These and other modifications and advantages will become even more apparent from the following detailed description of a preferred embodiment of the invention and from the drawings in which:

FIG. 1 is a plot showing the relationship between the thickness of the oxide film growing on a chip with copper pads and the temperature of a heating stage;

FIG. 2 is a schematic view illustrating the components for spraying a shielding gas according to this invention;

FIG. 3a and FIG. 3b include schematic views illustrating a shield gas browse forming a shield in the form of a dome and an air curtain over the surfaces of copper pads;

FIG. 4 illustrates the distribution profiles of the amount of oxygen atoms along the depth within the surfaces of the copper pads after curing;

FIG. 5 is a SEM micrograph showing successful thermosonic bonding of metal wires to the chip with copper pads according to this invention;

FIG. 6 is a SEM micrograph showing failed thermosonic bonding of metal wires to the chip with copper pads under the air atmosphere;

FIG. 7 is a comparative plot showing the relationships between the bondability of the bonding between metal wires and chips with copper pads and the temperature of the heating stage under inert gas shielded conditions according to this invention, and under those at the atmosphere;

FIG. 8 is a comparative plot showing the relationships between the bonding strength of metal wires to chips with copper pads and the temperature of the heating stage under inert gas shielded conditions according to this invention, and under those at the atmosphere;

FIG. 9 illustrates the distribution profiles of the amount of oxygen atoms along the depth within the surfaces of the copper pads where the chips with copper pads are shielded by argon according to this invention after heated on a heating stage;

FIG. 10 illustrates the distribution profiles of the amount of oxygen atoms along the depth within the surfaces of the copper pads where the chips with copper pads are heated on a heating stage under the atmosphere.

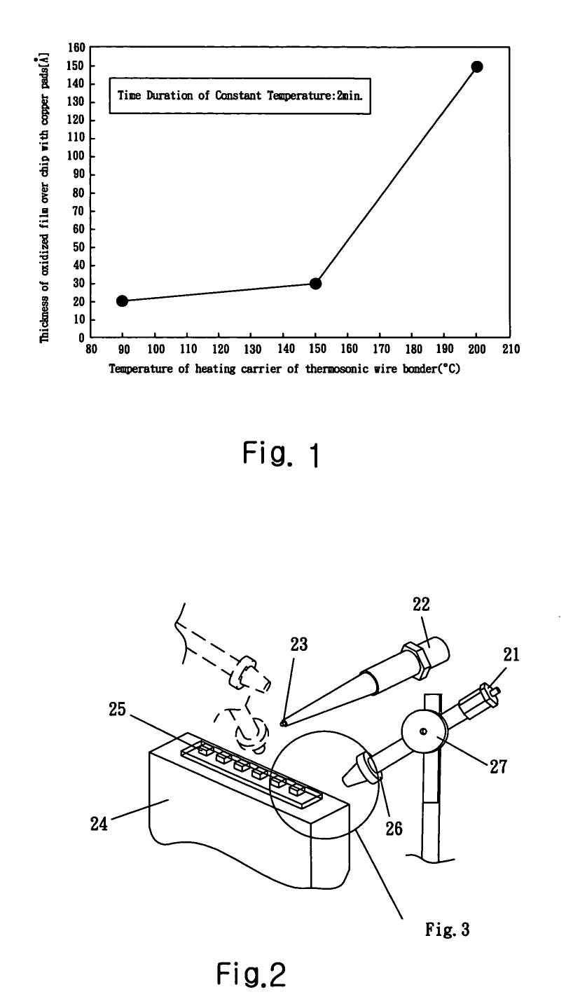

### DETAILED DESCRIPTION OF THE INVENTION (PREFERRED EMBODIMENTS)

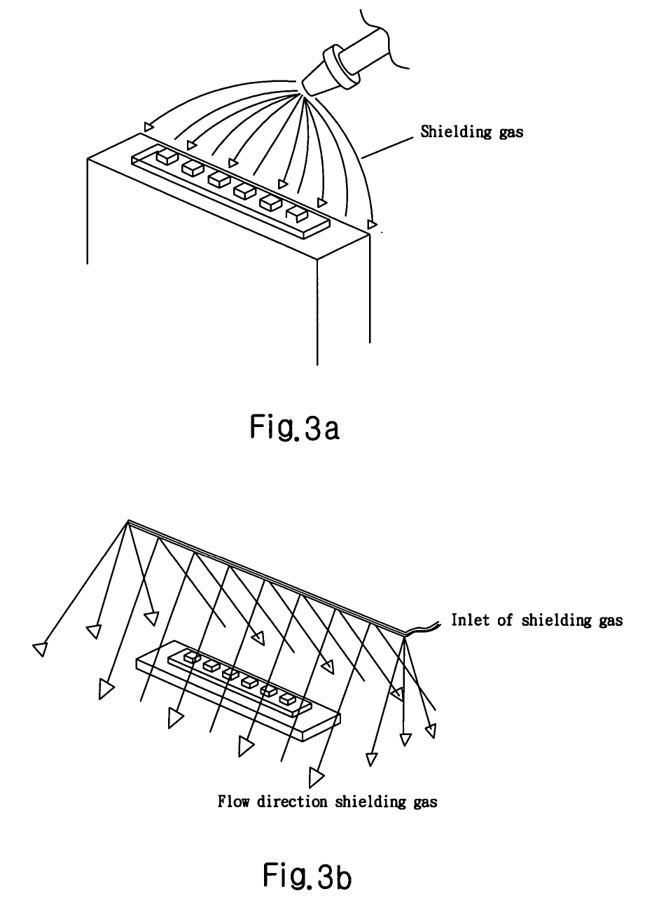

According to this invention, the process of thermosonic wire bonding between metal wires and chips with copper pads, the chips with copper pads located at a wire bonding zone on the heating stage is shielded by a inert gas shielding browse to prevent the surfaces of copper pads on the chips from oxidizing due to heating during thermosonic wire bonding, such that metal wires may be directly bonded to the copper pads by means of thermosonic bonding. Not only is this invention an effective means for thermosonic wire bonding of metal wires to chips with copper pads which meets the demand of perfect bondability required by the semiconductor packaging industry, but also ensure superior performance of the chips with copper pads, improve the bonding strength between the metal wires and copper pads, and enhance the reliability of the thermosonic wire bonding process for bonding of metal wires to chips with copper pads. In a shielding gas spraying device of this invention, as shown in FIG. 2, a shield consisting of a shielding gas browse forms a shielding zone in the form of a dome (FIG. 3a) or an air curtain (FIG. 3b) over the surfaces of chips with copper pads. However, these embodiments do not intend to limit the shielding configurations as shown in FIG. 3a and FIG. 3b. The shielding gas spraying device includes a shielding gas control valve 21 for controlling the flow rate, on/off of the shielding gas spray. The control valve 21 acts synchronously with a leadframe feeding device of a thermosonic wire bonder. When the leadframe feeding device of the wire bonder is activated to feed a leadframe onto the heating stage, the control valve 21 is activated at the same time to supply the shielding gas to shield the copper pads and to prevent the copper pads from oxidizing. After all copper pads on the leadframe have been subjected to the thermosonic wire bonding process, the leadframe unloading device is then activated and the control signal is transmitted to the shielding gas control valve 21 at the same time to switch off the control valve 21, preventing unnecessary consumption of the shielding gas. This control module effectively reduces the consumption of the shielding gas. The shielding gas spraying device further includes a shielding gas shielding range adjusting device 27 for adjusting height and orientation of the shielding gas browse to accommodate chips with copper pads of different specifications and dimensions, such that the device according to this invention can be applied to all kinds of chips with copper pads. Since broken or unsuccessful bonds are sometimes found after an automatic thermosonic wire bonding process is conducted, such that a manual wire-inserting operation may be required, the shielding gas spraying device of this invention should not interfere the handling space required for manual wire-inserting operation performed by the operators. That is, the operation efficiency of the thermosonic wire bonder would not be affected with the implementation of this invention.

The following embodiments that adopt the process and the chips with copper pads of this invention by subjecting the metal wires and chips with copper pads to the thermosonic wire bonding process, are discussed to show the effectiveness of this invention, but do not intend to limit the scope of the invention.

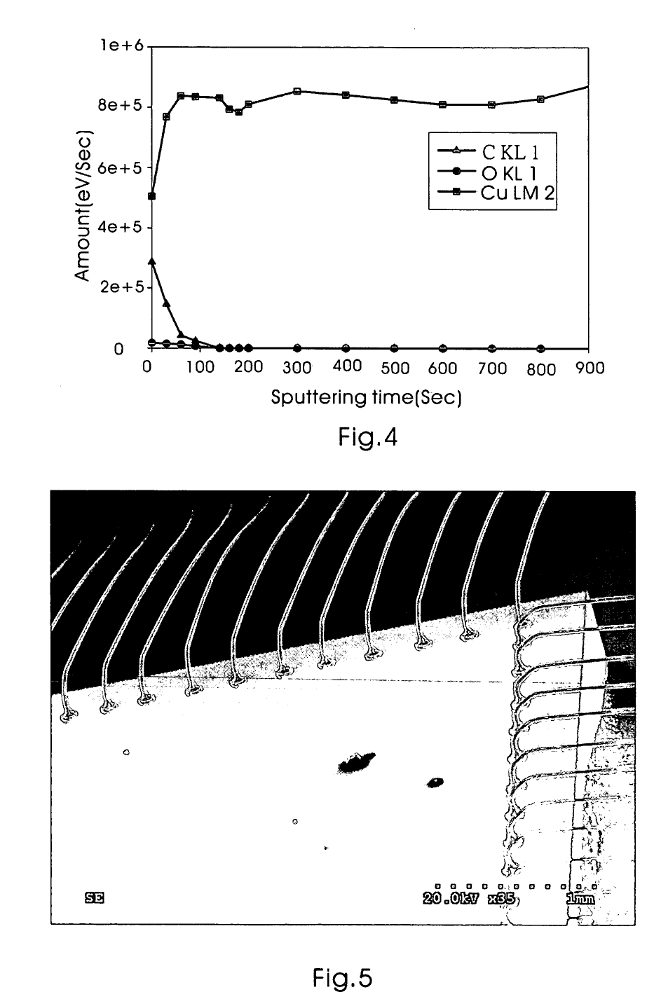

Chips with copper pads are mounted on a leadframe, with a wafer dimensioned to 6 mm×6 mm. The leadframe is made of copper alloy C7025. A second stitch bond is deposited on a surface thereof with a silver film to improve the stitch bond quality of the second thermosonic stitch bond of the metal wires. The model number of the leadframe is 128-362×362, where each leadframe includes six chips and each chip includes 128 copper pads. To prevent rapid growth of copper oxide film on the surfaces of the copper pads during die sawing and die mounting of the wafer, the chips are shielded by nitrogen for 30 minutes at 150° C. during curing in the die mounting process. To ensure accurate experimental results, an Auger electron spectrometer (AES) is used to analyze the surface of the chips with copper pads mounted on the leadframe, and to detect the distribution profiles of the amount of oxygen atoms along the depth within the surfaces of the copper pads, as shown in FIG. 4. It is found that the surfaces of copper pads contain only minimum amount of oxygen, which reveals a minimum degree of oxidization on the surfaces of copper pads so as not to cause failure of the subsequent thermosonic wire bonding. The shielding gas employed in this embodiment is commercially available argon (99.99%) with very high purity. Because the specific weight of argon is 23% higher than air, the argon is able to effectively prevent air from entering the argon shielding zone. The shielding gas spraying device as adopted in this embodiment is illustrated in FIG. 2. The parameters employed in the thermosonic wire bonding process are as shown in Table I.

TABLE I

| | |
|---|---|
| Ultrasonic power | 0.15 W (with a scale configured |
| | to 100 on the control panel) |
| Bonding load | 0.5 N |
| Bonding time | 20 ms |
| Temperature of heating stage | 90-220° C. |
| Metal wires diameter | 25 μm |

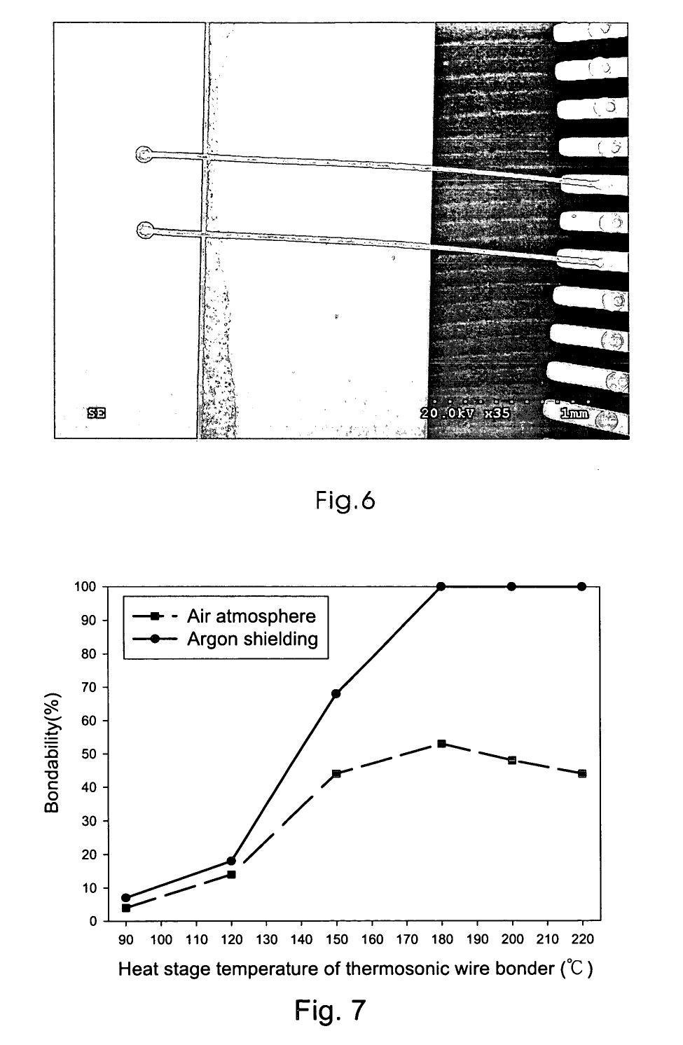

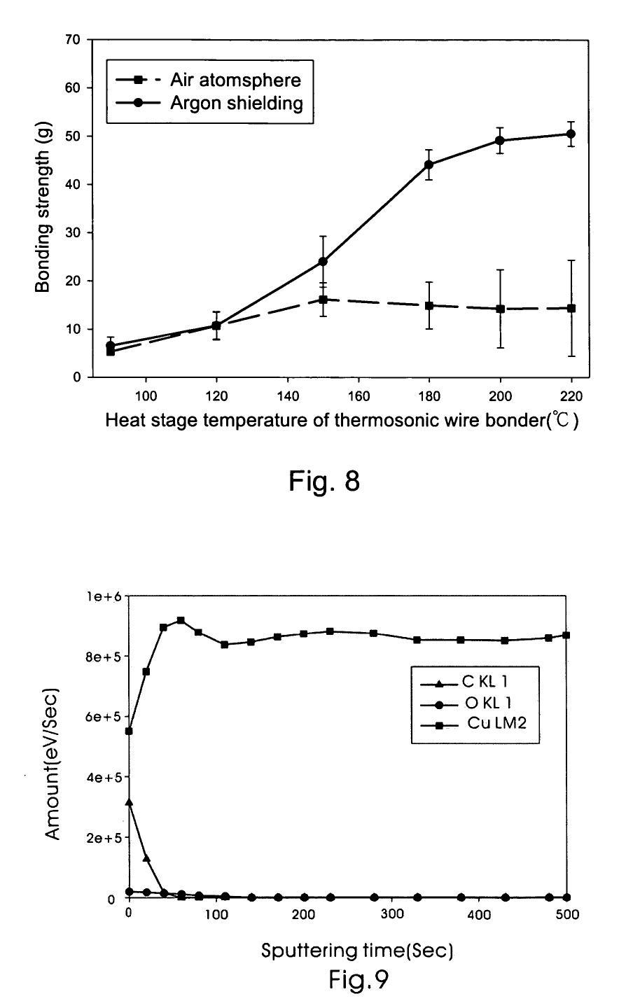

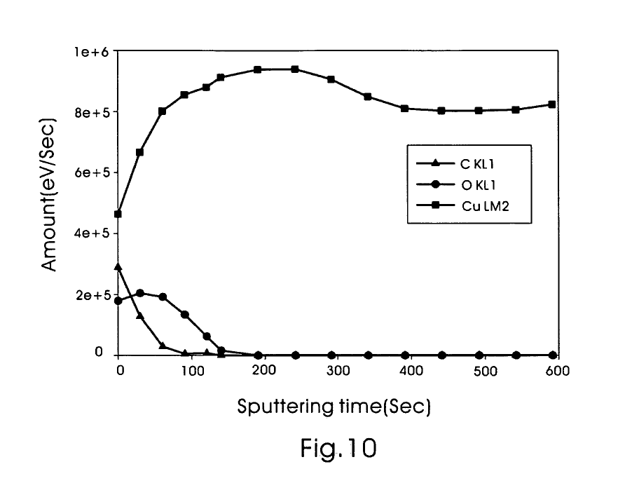

In a thermosonic wire bonding process where the copper pads are not subjected to a shielding gas, the samples as selected and the parameters of the thermosonic wire bonding are identical to those where the copper pads are subjected to a shielding gas. FIGS. 5 and 6 show the SEM micrographs of a successful thermosonic wire bonding of metal wires to the chip with copper pads according to this invention and a failed example of thermosonic bonding of metal wires to the chip with copper pad under the atmosphere respectively. It is known from FIG. 5 that, by using the shielding gas spraying device of this invention, 100% of the metal wires are directly bonded to the copper pads. On the contrary, in the case where a shielding gas spraying device is not employed, most of the metal wires failed to be bonded to the copper pads. Since the first bond on copper pads failed, metal wires are subsequently brought and bonded to leadframe by the bonding capillary. If the temperature of the heating stage is varied from 90° C. to 220° C. and all others parameters remain unchanged, the bondability and the bonding strength of metal wires to the chips with copper pads is significantly influenced by the temperature, as shown in FIGS. 7 and 8. In the case where a shielding gas is employed, the bondability reaches 100% at higher temperature range from 180° C.-220° C. On the other hand, in the case where no shielding gas is employed, bondability decreases with increasing temperature in the temperature range between 180° C. and 220° C. Within such a high temperature range, the surfaces of copper pads oxidize seriously when not shielded by the shielding gas, whereby the copper oxide film grows rapidly, causing failure of bonding between metal wires and the copper pads. FIG. 8 illustrates the relationship between bonding strength of the stitch bonds to copper pads and the stage temperature where no shielding gas is employed. Since the surfaces of copper pads oxidize and the copper oxide film grows rapidly, thereby resulting in a poor bonding strength between the metal wires and copper pads, which is far below the value required by the industry specifications [1]. On the other hand, in the case where shielding gas is employed, the bonding strength exceeds far beyond the requirements in the industry standards and increases with increasing stage temperature. This is due to the fact that a higher heating temperature provides higher activation energy to facilitate the inter-diffusion bonding between metal wires and copper pads. To show the effectiveness of shielding provided by this invention in preventing copper pads from oxidization, chips with copper pads are placed on the heating stage of the wire bonder for 2 minutes at 220° C., where a shielding gas is employed to shield the copper pads in one group, while the other group of chips is heated under the atmosphere. An AES is used to analyze the two groups of chips with copper pads, and to detect the distribution profiles of the amount of oxygen atoms along the depth within the surfaces of copper pads, as shown in FIGS. 9 and 10, respectively. Upon comparing the oxygen atom distribution profiles of chips with copper pads that are placed on the heating stage of the thermosonic wire bonder with those of the chips with copper pads right after curing (FIG. 4), one can easily observe that the oxygen atom depth profiles for chips shielded by the shielding gas, and those for chips right after curing are extremely similar. Such a result indicates that the gas shielding is able to effectively prevent the copper pads from oxidation during heating. On the other hand, the amount of the oxygen atoms found within the surfaces of the copper pads that are heated under the atmosphere is higher than that found within the surfaces copper pad right after curing. That is, the copper oxide film on the surfaces of the chips with copper pads grows rapidly under the atmosphere, causing failure in bonding the metal wires to the copper pads. The afore-described examples show that, not only can the shielding gas spraying device of this invention allows direct bonding of the metal wires to the chips with copper pads, but also effectively improve the bondability and bonding strength between the metal wires and chips with copper pads, and enhance the reliability of the thermosonic wire bonding process for metal wires and chips with copper pads.

The present invention has been described with a preferred embodiment thereof and it is understood that the scope and the spirit of the invention as defined by the appended claims.

What is claimed is:

1. A method of realizing direct bonding between metal wires and copper pads by means of thermosonic wire bonding using a shielding gas spraying device, comprising the steps of:
providing a shielding gas spraying device during thermosonic wire bonding between metal wires and chips with copper pads; and
providing a shielding gas to shield a surface of the chip with copper pads, wherein the shielding gas forms a shielding zone above the chip with copper pads to prevent air from entering the shielding zone and surfaces of copper pads from oxidization, so as to allow direct thermosonic bonding between metal wires and chips with copper pads.

2. The method of realizing bonding between metal wires and copper pads by means of thermosonic wire bonding using a shielding gas spraying device of claim 1, wherein:
the shielding gas browse forms a shielding range in a form of a dome or an air curtain over the surface of the chip with copper pads;
the shielding gas spraying device includes a control valve for controlling gas supply and flow rate, the control valve acts synchronously with a leadframe feeding and unloading system having a leadframe feeding device and a leadframe unloading device;
whereby when the leadframe feeding device of the thermosonic wire bonds is activated, the control valve is activated at the same time to supply the shielding gas to shield the chip with copper pads and to prevent oxidization of copper pads; and when the leadframe unloading device is activated upon completion of wire bonding, the control valve is switched off to cut the shielding gas supply.

3. The method of realizing direct bonding between metal wires and copper pads by means of thermosonic wire bonding using a shielding gas spraying device of claim 1, wherein the spraying device has an adjustable shielding range, capable of adjusting height and orientation of the shielding gas to accommodate chip specifications and chip size.

4. The method of realizing direct bonding between metal wires and copper pads by means of thermosonic wire bonding using a shielding gas spraying device of claim 1, wherein the shielding gas is selected from inert gases and reduction atmospheric gases, including: helium (He), argon (Ar), Nitrogen (N₂), Hydrogen (H₂), Carbon Dioxide (CO₂), or a gaseous combination of any two of the said gases of any proportion.
